(19) United States
(12) Patent Application Publication
(10) Pub. No.: US 2009/0008034 A1
(43) Pub. Date: Jan. 8, 2009

(54) PLASMA PROCESSING APPARATUS

(75) Inventors: Shigeru TAHARA, Yamanashi (JP); Eiichi NISHIMURA, Yamanashi (JP); Kumiko YAMAZAKI, Yamanashi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/165,871

(22) Filed: Jul. 1, 2008

Related U.S. Application Data
(60) Provisional application No. 60/973,786, filed on Sep. 20, 2007.

(30) Foreign Application Priority Data
Jul. 2, 2007 (JP) 2007-174447

(51) Int. Cl. H01L 21/306

(52) U.S. Cl. 156/345.35

(57) ABSTRACT

A plasma generation chamber and a processing chamber are isolated from each other by a barrier wall member disposed between them. The barrier wall member includes two plate members and stacked one on top of the other over a gap, a plurality of through holes and, via which hydrogen radicals are allowed to pass, are respectively formed at the plate member and the plate member. The through holes at one plate member are formed with an offset relative to the through holes formed at the other plate member and the plate members are both constituted of an insulating material that does not transmit ultraviolet light.

### CROSS-REFERENCE TO RELATED APPLICATIONS

This document claims priority to Japanese Patent Application Number 2007-174447, filed on Jul. 2, 2007 and U.S. Provisional Application No. 60/973,786, filed on Sep. 20, 2007, the entire content of which are hereby incorporated by reference.

### FIELD OF THE INVENTION

The present invention relates to a plasma processing apparatus that executes a specific type of processing on a processing target substrate with hydrogen radicals generated by exciting a processing gas containing hydrogen to plasma.

### BACKGROUND OF THE INVENTION

During a manufacturing process for manufacturing, for instance, semiconductor devices, a specific film formed on a processing target substrate such as a semiconductor wafer (hereafter may be simply referred to as a “wafer”) is selectively etched and removed by using a resist film formed at the surface of the wafer as a mask and then the resist film is removed through ashing. During the ashing process, oxygen radicals generated by exciting an oxygen-containing gas to a plasma state are used in the related art. As semiconductor elements today need to assume a multilayer structure with a greater number of wiring layers stacked one on top of another, a low dielectric constant film with a low dielectric constant, such as a low-k film, is frequently used as an insulating film in the multilayer wiring structure. Since such a low dielectric constant insulating film is readily damaged by oxygen radicals, hydrogen radicals with which damage can be more successfully inhibited are utilized when etching or ashing the low dielectric constant insulating film.

The plasma processing apparatuses that process wafers with radicals in the related art include those adopting a structure equipped with a plasma generation chamber where plasma is generated by exciting a processing gas and a processing chamber communicating with the plasma generation chamber (see, for instance, patent reference literatures 1 and 2 listed below). Since ions that are sure to damage films on a wafer are formed, in addition to radicals, from the plasma generated in the plasma generation chamber, a barrier wall member via which ions traveling from the plasma generation chamber toward the processing chamber are trapped but radicals are allowed to pass through is disposed between the plasma generation chamber and the processing chamber, in order to process the wafer with the radicals while minimizing damage to the wafer. More specifically, a plurality of through holes through which the radicals are allowed to travel are formed at the barrier wall member constituted of a metal such as aluminum and the potential at the barrier wall member is adjusted to, for instance, the ground level so as to attract and capture ions.

The barrier wall member in the related art is constituted with a single plate. However, at the barrier wall member constituted with a single plate, the through holes formed to let through the radicals are unblocked, giving rise to a concern that ultraviolet light (including vacuum ultraviolet light) generated as the processing gas is raised to plasma in the plasma generation chamber may be transmitted through the through holes. If the ultraviolet light is transmitted through the through holes and is directly radiated over the surface of the wafer, films deposited upon the wafer may become damaged and accordingly, the wafer needs to be shielded from the ultraviolet light. For instance, if a low-k film is formed on the wafer, the Si—C bond in the low-k film is broken by the ultraviolet light, allowing carbon to separate, which will result in an increase in the dielectric constant of the film. In addition, the low-k film will be rendered more hydrophilic and the water content in the film will increase to result in a decrease in the mechanical strength of the film. This issue is addressed in the related art by forming the barrier wall member with two plate members and forming through holes at the individual plate members with an offset relative to each other so as not to transmit the ultraviolet light.

Since the barrier wall member in the related art is constituted of a metal such as aluminum and its potential is adjusted to, for instance, ground level, as explained earlier, a significant electrical potential is generated between the barrier wall member and the hydrogen plasma. Thus, the ions being captured at the barrier wall member are attracted toward the barrier wall member with a significant force and collide with the surface of the barrier wall member at high velocity. Under these circumstances, the metal surface of the barrier wall member is likely to become sputtered by the ions.

If the metal surface of the barrier wall member is sputtered by ions, as described above, metal atoms let out from the barrier wall member surface will scatter into the space inside the processing chamber as particles and the members installed inside the processing chamber and the wafer are bound to become contaminated by the metal atoms. The barrier wall member, constituted with two plate members with through holes formed therein with an offset relative to each other in order to block ultraviolet light as described above, is particularly problematic. Namely, ions formed from the plasma has a tendency to advance through rectilinear propagation and thus cannot pass through the barrier wall member via the through holes formed at the two plate members. In this situation, a majority of the ions retaining a high level of energy will collide with the surface of either plate member and sputter the collision site. In other words, ion collisions are bound to occur more readily at the double-plate barrier member than at the barrier wall member constituted with a single plate and more metal atoms are bound to be ejected from the surfaces of the individual plate members sputtered by the ions.

As described above, there is a concern with regard to the barrier wall member constituted with a plurality of plate members formed by using a metal such as aluminum in that a greater number of metal atoms will scatter into space as the barrier wall member is sputtered by ions, resulting in a significant quantity of particles settling onto the wafer and serious metal contamination.

Patent reference literature 3 listed below discloses a structure that includes a single shield plate with a plurality of through holes formed therein, disposed between a reaction chamber where plasma is generated and a processing chamber where a wafer is processed. The shield plate disclosed in the publication is constituted of an insulating material such as quartz, instead of a metal which is bound to become thermally deformed. However, the level of force with which ions are attracted to a single shield plate constituted of an insulating material instead of a grounded metal is bound to be low, and ions will be allowed to pass through the through holes at the shield plate to reach the wafer and damage the film formed on the wafer. Accordingly, the holes formed at the shield plate in patent reference literature 3, via which radicals travel through, assume a smaller diameter, so as to disallow passage of ions.

However, ultraviolet light generated from the plasma will still travel through the through holes with a smaller diameter and the ultraviolet light having reached the wafer may damage the film on the wafer. Furthermore, the quantity of radicals to be used in a specific type of processing on the wafer such as etching, ashing or film formation, will also be reduced when the through holes assume a smaller diameter to result in a lower processing rate.

It is to be noted that while patent reference literature 3 also discloses a layered shield plate formed by stacking a metal mesh over an insulator match to assure a better ion trapping function, the issue of ultraviolet light passing through this shield plate, similar to the issue in the shield plate constituted with a single layer shield plate remains unaddressed, since the through holes are not offset. In addition, the presence of even a single metal mesh sheet in the shield plate is likely to induce metal contamination inside the processing chamber.
(patent reference literature 1) Japanese Laid Open Patent Publication No. 2006-073722
(patent reference literature 2) Japanese Laid Open Patent Publication No. 2002-083803
(patent reference literature 3) Japanese Laid Open Patent Publication No. H08-148473

### SUMMARY OF THE INVENTION

Accordingly, an object of the present invention, having been completed by addressing the issues discussed above, is to provide a plasma processing apparatus equipped with a barrier wall member via which hydrogen radicals alone can be supplied into a processing chamber by blocking the advance of ultraviolet light and hydrogen ions generated from plasma formed inside a plasma generation chamber and the hydrogen ions can be captured with a high level of reliability while effectively preventing entry of scattered metal ions and scattered pieces of the plate member material into the processing chamber.

The object described above is achieved in an aspect of the present invention by providing a plasma processing apparatus that executes a specific type of processing on a processing target substrate with hydrogen radicals generated by exciting a hydrogen-containing processing gas to a plasma state, comprising, a plasma generation chamber where plasma is generated by exciting the processing gas, a processing chamber communicating with the plasma generation chamber, a stage disposed inside the processing chamber upon which the processing target substrate is placed, and a barrier wall member separating the plasma generation chamber from the processing chamber. The barrier wall member in this plasma processing apparatus includes a plurality of plate members stacked one on top of the other with a gap between them. A plurality of through holes through which the hydrogen radicals travel are formed at each of the plate members, the through holes at a given plate member are formed with an offset relative to the through holes at another plate member so that the through holes at the different plate members are not aligned with each other, and the plate members are all constituted of an insulating material through which ultraviolet light cannot be transmitted.

According to the present invention described above, the barrier wall member separating the plasma generation chamber from the processing chamber is formed by using a plurality of plate members through which ultraviolet light cannot pass and the through holes at one plate member are formed with an offset relative to the through holes at another plate member. The ultraviolet light and the hydrogen ions among ultraviolet light, hydrogen ions and hydrogen radicals generated as the hydrogen-containing processing gas is excited to a plasma state, which tend to travel in a straight line, cannot pass through both sets of the through holes formed at the two insulating plate members. In other words, they are bound to be blocked at the surface of one or other of the plate members. The hydrogen radicals, on the other hand, which do not propagate in a rectilinear manner, are able to pass through the through holes at all the plate members. Consequently, only the hydrogen radicals are allowed to reach the processing target substrate to be used in the specific processing executed on the substrate, without damaging the substrate with ultraviolet light or hydrogen ions.

Since the plurality of plate members constituting the barrier wall member according to the present invention are all formed by using an insulating material, no metal atoms are scattered even in the event of a collision with ions. Furthermore, the level of force with which hydrogen ions are attracted to the barrier wall member according to the present invention can be more easily regulated compared to a barrier wall member constituted with a plurality of metal plate members and thus, the energy with which the hydrogen ions collide with the plate members, too, can be minimized. In other words, even though the likelihood of hydrogen ions colliding with the plurality of plate members having through holes formed therein with an offset relative to each other is very high compared to the likelihood of collisions occurring at a barrier wall member constituted with single plate member, the force with which the ions are attracted is relatively low and the surfaces of the plate members are less likely to become sputtered, since the individual plate members assume an electrically floating state. As a result, the material constituting the plate members is not scattered and consequently, entry of particles of the plate member material into the processing chamber is prevented. Even though the plate members are in an electrically floating state, a sheath is formed at their surfaces and an electrical potential high enough to capture hydrogen ions is generated via the sheath between the barrier wall member and the hydrogen plasma. Thus, with the barrier wall member according to the present invention, the hydrogen ions can be captured with a high level of reliability while effectively preventing entry of scattered metal atoms and scattered plate member material into the processing chamber.

It is desirable that the plate members be constituted of a material containing, for instance, silicon oxide. Alternatively, the plate members may be constituted of a material containing aluminum oxide. Even when hydrogen ions collide with the plate members constituted of either of these materials, no metal pieces will be scattered into the processing chamber. Since the hydrogen ions collide with the plate members with a low level of force, the material constituting the plate members sputtered from the surfaces of the plate members will simply settle back onto the surfaces of the plate members instead of becoming completely separated from the plate member surfaces and entering the processing chamber. The substance having become deposited on the plate members can be removed simply by wiping the surfaces with a specific type of chemical such as hydrogen fluoride.

The area within the surface plane of at least one of the plurality of plate members may include a central area with no through holes formed therein and an outer area located further outward relative to the central area, where the plurality of through holes are formed. Through these measures, the quantity of hydrogen radicals supplied over to the processing target substrate can be regulated so that they are supplied in a smaller quantity over to an area near the center compared to the quantity of hydrogen radicals supplied toward the edge of the processing target substrate. This means that even in an environment in which hydrogen radicals tend to concentrate near the center of the processing target substrate rather than in the peripheral area of the processing target substrate, hydrogen radicals can be supplied evenly over the entire surface of the processing target substrate, which, in turn, improves the in-plane uniformity of the processing.

Alternatively, the in-plane area of at least one of the plurality of plate members may include a central area and a ring-shaped area surrounding the central area, where no through holes are formed, and an area located between the central area and the ring-shaped area and an outer area located further outward relative to the ring-shaped area, where the through holes are formed. Through these measures, the quantity of hydrogen radicals to be supplied over to the processing target substrate can be regulated over the middle area between the center of the processing target substrate and the edge thereof, as well as near the center of the processing target substrate, which, in turn, further improves the uniformity with which the processing target substrate is processed.

As a further alternative, over the in-plane area of at least one of the plurality of plate members, the plurality of through holes may be formed so that the density of through holes, which are formed relatively sparsely at the center, increases toward the edge of the plate member. Through these measures, too, the quantity of hydrogen radicals to be supplied over to the processing target substrate can be regulated so that they are supplied in a smaller quantity over to an area near the center of the processing target substrate relative to the quantity of hydrogen radicals supplied to an area near the edge of the processing target substrate, which, in turn, improves the uniformity with which the processing target substrate is processed.

As yet another alternative, the diameter of the plurality of through holes formed at the Inn-plane area of at least one of the plurality of plate members may assume the smallest value at the center and increased toward the edge of the plate member. Through these measures, too, the quantity of hydrogen radicals to be supplied over to the processing target substrate can be regulated so that they are supplied in a smaller quantity over to an area near the center of the processing target substrate relative to the quantity of hydrogen radicals supplied to an area near the edge of the processing target substrate, which, in turn, improves the uniformity with which the processing target substrate is processed.

It is to be noted that the description in the specification is provided by assuming that 1 Torr=(101325/760) Pa and that 1 sccm=(10⁻⁶ /60) m³/sec.

According to the present invention, hydrogen radicals generated from plasma formed in the plasma generation chamber can be selectively supplied into the processing chamber by blocking ultraviolet light and hydrogen ions also generated from the plasma and the hydrogen ions can be captured with a high level of reliability while ensuring that scattered metal atoms and scattered pieces of the material constituting the plate members do not enter the processing chamber.

### BRIEF DESCRIPTION OF THE DRAWINGS

FIG. 1 is a longitudinal sectional view schematically illustrating the structure adopted in the plasma processing apparatus achieved in an embodiment of the present invention

FIG. 2 is a plan view of the barrier wall member in FIG. 1 taken from the plasma generation chamber side, illustrating an example of a positional arrangement that may be adopted with regard to the positions of the through holes formed at the individual plate members constituting the barrier wall member in the embodiment;

FIG. 3 illustrates the function of the barrier wall member achieved in the embodiment, in an enlargement of some of the through holes formed at the plate members in FIG. 1;

FIG. 4 presents the results of tests conducted to confirm the advantages achieved by installing the barrier wall member in the embodiment;

FIG. 5 presents a graph of an ashing rate distribution within the wafer surface plane, observed by executing an ashing process in a plasma processing apparatus with the barrier wall member disengaged;

FIG. 6A is a plan view of an example of a positional arrangement that may be adopted in conjunction with through holes at the lower plate member at which no through holes are formed over a central area;

FIG. 6B is a longitudinal sectional view, schematically illustrating the barrier wall member constituted with the upper plate member shown in FIG. 1 and the lower plate member shown in FIG. 6A;

FIG. 7 presents a graph of an ashing rate distribution within the wafer surface plane observed by executing an ashing process in a plasma processing apparatus with the barrier wall member in FIG. 6B installed therein;

FIG. 8A is a plan view of an example of a positional arrangement that may be adopted in conjunction with through holes at the lower plate member at which no through holes are formed over a central area and a ring-shaped area;

FIG. 8B is a longitudinal sectional view, schematically illustrating the barrier wall member constituted with the upper plate member shown in FIG. 1 and the lower plate member shown in FIG. 8A; and

FIG. 9 presents a graph of an ashing rate distribution within the wafer surface plane observed by executing an ashing process in a plasma processing apparatus with the barrier wall member in FIG. 8B installed therein.

### DETAILED DESCRIPTION OF THE PREFERRED EMBODIMENT

The following is a detailed explanation of the preferred embodiment of the present invention, given in reference to the attached drawings. It is to be noted that in the description and the drawings, the same reference numerals are assigned to components having substantially identical functions and structural features to preclude the necessity for a repeated explanation thereof.

### (Structural Example for the Plasma Processing Apparatus)

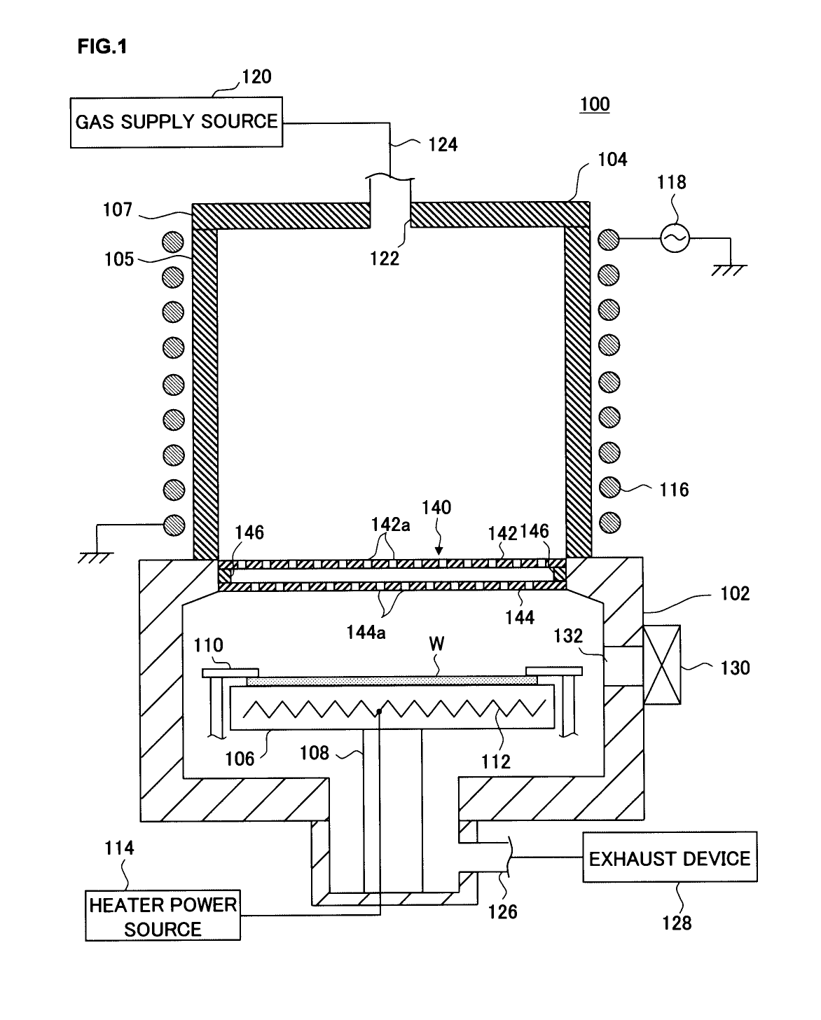

First, in reference to a drawing, a structural example that may be adopted in the plasma processing apparatus achieved in an embodiment of the present invention is explained. The following explanation is provided by assuming that the present invention is adopted in a down-flow type plasma processing apparatus that processes substrates by using hydrogen radicals generated from plasma (hereafter may be referred to as “hydrogen plasma”) raised from a hydrogen-containing processing gas. FIG. 1 is a longitudinal sectional view schematically illustrating the structure of the plasma processing apparatus 100 achieved in the embodiment. In the plasma processing apparatus 100, a photoresist film formed on a low dielectric constant insulating film with a lower dielectric constant is removed through ashing by supplying hydrogen radicals over to a wafer W having the lower dielectric constant insulating film, such as a low-k film, formed thereupon.

As shown in FIG. 1, the plasma processing apparatus 100 includes a processing chamber 102 where the wafer W is processed and a plasma generation chamber 104 communicating with the processing chamber 102, where plasma is generated by exciting a processing gas. The plasma generation chamber 104, located above the processing chamber 102, is structured so that plasma is generated through an inductively coupled plasma method from the processing gas delivered therein.

More specifically, the plasma generation chamber 104 includes a substantially cylindrical reaction container 105 constituted of an insulating material such as quartz or ceramic. The top of the reaction container 105 is sealed off with a detachable lid 107 so as to assure a high level of airtightness. A gas delivery port 122 is formed at the top of the reaction container 105 and a specific type of processing gas originating from a gas supply source 120 is delivered into the internal space of the plasma generation chamber 104 via the gas delivery port 122. Although not shown, a switching valve via which a gas piping 124 is opened/closed, a mass flow controller that regulates the flow rate of the processing gas and the like are disposed at the gas piping 124 connecting the gas supply source 120 to the gas delivery port 122.

The processing gas is a hydrogen-containing gas with which hydrogen radicals (H*) can be generated. Such a processing gas may be constituted with hydrogen gas alone or it may be a mixed gas containing hydrogen gas and an inert gas. The inert gas in the mixed gas may be, for instance, helium gas, argon gas or neon gas. It is to be noted that when a mixed gas containing hydrogen gas and an inert gas is used as the processing gas, the hydrogen gas should be mixed with a mixing ratio of, for instance, 4%.

A coil 116 to be used as an antenna member is wound around the outer circumference of the reaction container 105. A high-frequency power source 118 is connected to the coil 116. High-frequency power with its frequency set in a range of 300 kHz˜60 MHz can be output from the high-frequency power source 118. As a specific high-frequency power with a frequency of, for instance, 450 kHz is supplied from the high-frequency power source 118 to the coil 116, an induction field is formed inside the plasma generation chamber 104. As a result, the processing gas delivered into the processing chamber 102 becomes excited and is raised to plasma.

A disk-shaped stage 106, upon which a wafer W can be supported levelly, is disposed inside the processing chamber 102. The stage 106 is supported by a cylindrical support member 108 disposed at the bottom of the processing chamber 102. The stage 106 is constituted of ceramic such as aluminum nitride. A clamp ring 110, which clamps the wafer W placed on the stage 106, is disposed at the outer edge of the stage 106. In addition, a heater 112 that heats the wafer W is installed within the stage 106. As power is supplied to the heater 112 from a heater power source 114, the heater 112 heats the wafer W to a predetermined temperature (e.g., 300° C.). It is desirable that the predetermined temperature be set within a relatively high temperature range of, for instance, 250° C.˜400° C., over which the low dielectric constant insulating film remains substantially undamaged.

An exhaust pipe 126 is connected to the bottom wall of the processing chamber 102 and an exhaust device 128, which includes a vacuum pump, is connected to the exhaust pipe 126. As the exhaust device 128 is engaged in operation, the pressure in the processing chamber 102 and the plasma generation chamber 104 can be lowered to achieve a predetermined degree of vacuum.

At the side wall of the processing chamber 102, a transfer port 132 that can be opened/closed via a gate valve 130 is formed. The wafer W is carried into/out of the processing chamber via a transfer mechanism such as a transfer arm (not shown).

The edge of the open bottom of the reaction container 105 constituting the plasma generation chamber 104 is set at the edge of the open top of the processing chamber 102. Near the position at which the reaction container is mounted at the processing chamber, a barrier wall member 140 is detachably installed so as to separate the processing chamber 102 from the plasma generation chamber 104. The barrier wall member 140 may be mounted at the inner wall of the edge of the opening at the processing chamber 102, as shown in FIG. 1. It is to be noted that the mounting position of the barrier wall member 140 is not limited to that shown in FIG. 1. As long as it separates the plasma generation chamber 104 from the processing chamber 102, it may be installed at the plasma generation chamber 104 or it may be installed astride both the plasma generation chamber 104 and the processing chamber 102. The barrier wall member 140 is structured so that only hydrogen radicals generated as a hydrogen-containing processing gas is excited to plasma in the plasma generation chamber 104, are allowed to pass through the barrier wall member. Namely, as the hydrogen-containing processing gas is excited and plasma is generated, hydrogen radicals, hydrogen ions, ultraviolet light and the like are formed. Of those, the hydrogen ions and the ultraviolet light are blocked at the barrier wall member and the hydrogen radicals alone are allowed to pass through toward the processing chamber 102 via the barrier wall member. It is to be noted that specific examples of the barrier wall member 40 are to be described later.

A wafer W to be processed with hydrogen radicals in the plasma processing apparatus 100 structured as described above is first carried into the processing chamber 102 through the transfer port 132 by opening the gate valve 130. Once the wafer W is placed in the processing chamber 102, it is transferred onto the stage 106 where it is held fast by the clamp ring 110.

Subsequently, the gate valve 130 is closed and the processing chamber 102 and the plasma generation chamber 104 are evacuated by the exhaust device 128 until the pressure inside is reduced to a predetermined degree of vacuum. In addition, the level of power to be supplied from the heater power source 114 to the heater 112 is selected so as to heat the wafer W to a predetermined temperature (e.g., 300° C.).

Then, high-frequency power (e.g., 4000 W) is supplied to the coil 116 from the high-frequency power source 118 while supplying the processing gas constituted with a hydrogen-containing gas from the gas supply source 120 into the plasma generation chamber 104 via the gas delivery port 122, thereby forming an induction field inside the plasma generation chamber 104 and consequently generating hydrogen plasma inside the plasma generation chamber 104. From the hydrogen plasma, ultraviolet light, hydrogen ions and hydrogen radicals are formed. Of these, the ultraviolet light and the hydrogen ions are blocked at the barrier wall member 140 and the hydrogen radicals alone are allowed to pass through the barrier wall member. Thus, a desired type of processing such as ashing of a photoresist film present on the wafer W can be executed by using the hydrogen radicals alone without damaging the surface of the wafer W in the processing chamber 102 with the ultraviolet light or the hydrogen ions. This advantage is particularly significant when a low dielectric constant insulating film with a low dielectric constant, such as a low-k film, is formed on the wafer W, since the low dielectric constant film, readily damaged by ultraviolet light and hydrogen ions, is effectively protected by blocking the ultraviolet light and the hydrogen ions.

It is to be noted that while an explanation is given above on an example in which the hydrogen plasma is generated in the plasma generation chamber 104 through the inductively coupled plasma method, the present invention is not limited to this example and hydrogen plasma may be generated instead through, for instance, a microwave excitation method.

### (Structural Examples for the Barrier Wall Member)

Next, specific structural examples that may be adopted in the barrier wall member 140 in the embodiment are explained in reference to drawings. As shown in FIG. 1, the barrier wall member 140 is formed by stacking a plurality of plate members on top of one another with a gap between them. In the example presented in FIG. 1, two disk-shaped plate members, i.e., an upper plate member 142 and a lower plate member 144, constitute the barrier wall member 140. It is to be noted that a spacer 146 is disposed between the upper plate member 142 and the lower plate member 144 along the circumferential edges thereof at a position at which the presence of the spacer does not interfere with any other structural element (e.g., at an area where through holes 142a and 144a to be detailed later are not formed). With the spacer 146, the gap between the two plate members is held at a uniform distance. The spacer 146 may hold the gap between the upper plate member 142 and the lower plate member 144 to a predetermined distance of, for instance, 5 mm.

The upper plate member 142 and the lower plate member 144 are both constituted of an insulating material that does not transmit ultraviolet light. The term “ultraviolet light” is used in this context to refer to light with a smaller wavelength than visible light, which may damage the wafer. It may be light with an even smaller wavelength than that of solar ultraviolet light, such as vacuum ultraviolet light, as well as the solar ultraviolet light. The insulating material through which such ultraviolet light is not transmitted may be a material containing aluminum oxide, as well as a material containing silicon oxide such as quartz. It is to be noted that the spacer 146 may be constituted of an insulating material similar to that constituting the upper plate member 142 and the lower plate member 144, or it may be constituted of a metal such as aluminum.

A plurality of through holes via which hydrogen radicals generated in the plasma generation chamber alone are allowed to pass are formed at each of the plate members, i.e., the upper plate member 142 and the lower plate member 144. More specifically, a plurality of through holes 142a passing from the upper surface (front surface) side to the lower surface (rear surface) side are formed at the upper plate member 142, whereas a plurality of through holes 144a passing from the upper surface (front surface) side to the lower surface (rear surface) side are formed at the lower plate member 144.

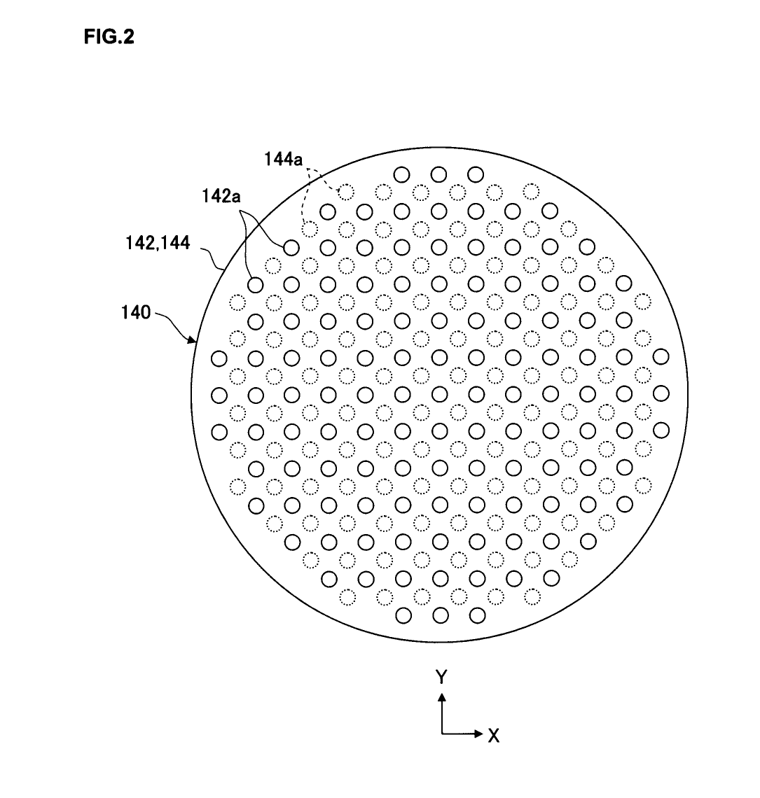

The through holes 142a at the upper plate member 142 and the through holes 144a at the lower plate member 144 are formed with an offset relative to each other so as to ensure that they do not range in line with each other. The through holes 142a and 144a may assume a positional arrangement such as that shown in FIG. 2. FIG. 2, presenting an example of a positional arrangement that may be assumed for the through holes 142a and 144a at the plate members 142 and 144 respectively, is a plane view of the barrier wall member 140 in FIG. 1, taken from the side on which the plasma generation chamber 104 is present. In this example, the through holes 142a and 144a are respectively formed over the entire surfaces of the plate members 142 and 144 in a matrix pattern with the individual through holes sent over equal intervals. It is to be noted that when the barrier wall member 140 is viewed from the side on which the plasma generation chamber 104 is present, the through holes 144a at the lower plate member 144 are concealed behind the solid portion of the upper plate member 142 where no through holes 142a are present and are actually not visible. The through holes 144a that are not visible are indicated by dotted lines and the through holes 142a are indicated by solid lines in FIG. 2. In addition, for purposes of simplification, FIG. 2 shows through holes 142a and 144a in quantities smaller than the actual numbers of through holes formed at the plate members.

As shown in FIG. 2, the through holes 142a are formed at the upper plate member 142 so that each of them assumes a position offset by a ½ pitch relative to the through holes 144a at the lower plate member 144 both along the X direction and the Y direction at the surface of the disk. Thus, the through holes 142a and the through holes 144a are formed to pass through the respective plate members with an offset relative to each other. In other words, when one views the barrier wall member 140 from the side on which the plasma generation chamber 104 is present, the line of sight is blocked by the barrier wall member 140 and thus, one cannot see the wafer W placed on the stage 106 inside the processing chamber 102. It is to be noted that the through holes 142a and 144a may be formed with an array pattern other than that shown in FIG. 2.

By forming the through holes 142a at the upper plate member 142 and the through holes 144a at the lower plate member 144 with an offset relative to each other so that they do not range in line with each other, ultraviolet light, hydrogen ions and the like with their tendency to travel in a straight line can be effectively blocked as plasma is generated in the plasma generation chamber 104.

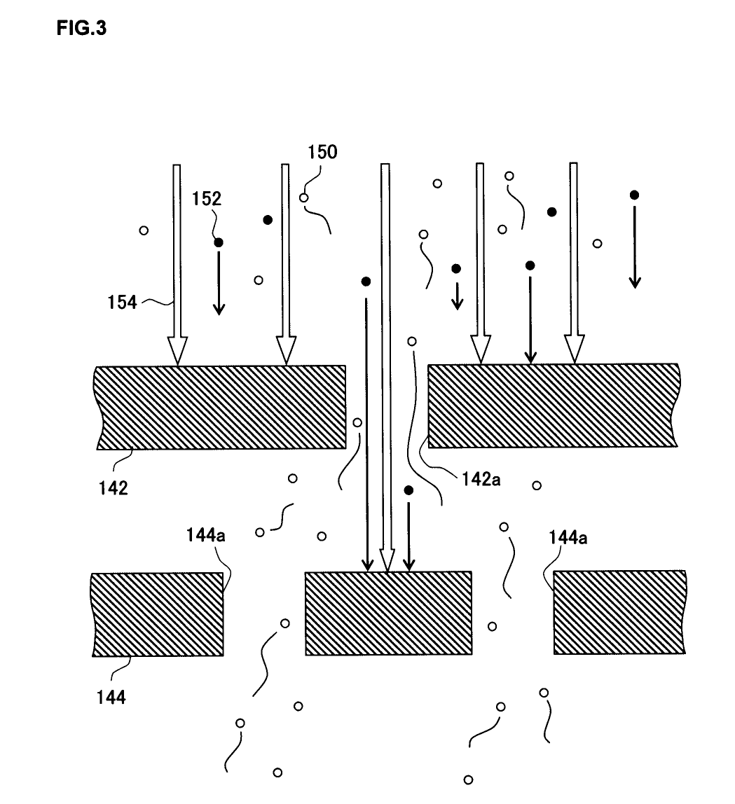

The action occurring at the barrier wall member 140 is now described in further detail in reference to a drawing. FIG. 3 illustrates the function of the barrier wall member 140 in an enlarged view of a through hole 142a at the upper plate member 142 and through holes 144a at the lower plate member 144 in FIG. 1. It is to be noted that hydrogen radicals 150, hydrogen ions 152 and ultraviolet light 154 are all schematically illustrated in FIG. 3 to facilitate the explanation.

As hydrogen plasma is generated in the plasma generation chamber 104, the barrier wall member 140 is exposed to a down-flow of the hydrogen radicals 150, the hydrogen ions 152 and the ultraviolet light 154 generated from the hydrogen plasma, as shown in FIG. 3. Among these, the hydrogen ions 152 and the ultraviolet light 154 with their tendency to travel in a straight line, travels along the vertical direction to reach the barrier wall member 140. Since the upper plate member 142 and the lower plate member 144 are constituted of a material that does not transmit ultraviolet light and the through holes 142a and 144a at the upper plate member 142 and the lower plate member 144 are formed with an offset relative to each other in the embodiment, the hydrogen ions 152 and the ultraviolet light 154 are blocked at the upper surface of the upper plate member 142 where the through holes 142a are not present, and even if they travel through the through holes 142a at the upper plate member 142, they will be blocked at the upper surface of the lower plate member 144.

The hydrogen radicals 150, which do not have as marked a tendency to advance in a straight line as the hydrogen ions 152 and the ultraviolet light 154, instead deviate as they travel. Thus, the hydrogen radicals are able to travel through both the through holes 142a at the upper plate member 142 and the through holes 144a at the lower plate member 144 even though the through holes at the two plate members are formed with an offset relative to each other.

As described above, the hydrogen ions 152 and the ultraviolet light 154 are blocked at the barrier wall member 140 and only the hydrogen radicals 150 are able to pass through the barrier wall member 140 to enter the processing chamber 102. Thus, the hydrogen radicals 150 alone are supplied over to the surface of the wafer W placed on the stage 106. The desired type of processing such as ashing of a photoresist film on the wafer W can then be executed by using the hydrogen radicals alone while the wafer W remains undamaged by ultraviolet light or hydrogen ions.

If the plurality of plate members constituting the barrier wall member 140 are formed by using a metal such as aluminum and the potential at the barrier wall member is adjusted to a level matching or lower than the ground potential, a significant electrical potential occurs between the barrier wall member 140 and the hydrogen plasma, inducing a high level of force with which the hydrogen ions 152 are attracted to the barrier wall member 140. While the hydrogen ions 152 can be captured more readily under these circumstances, they are bound to collide with the surface of either of the plate members constituting the barrier wall member 140 with higher velocity. Consequently, the metal surfaces of the plate members constituting the barrier wall member 140 will become sputtered with the hydrogen ions 152 and, as a result, metal atoms will scatter. Entry of the metal atoms into the processing chamber 102 may result in particles scattered onto the wafer W and metal contamination.

Furthermore, at a barrier wall member 140 such as that in the embodiment constituted with two or more plate members, e.g., the upper plate number 142 and the lower plate member 144, with through holes formed at the plate members with an offset relative to each other, hydrogen ions having passed through a through hole at an upper plate member are likely to collide with the surface of a lower-layer plate member and thus, hydrogen ion collision tends to occur more readily. This means that hydrogen ions 152 are likely to collide with the surfaces of the plate members constituting a barrier wall member more readily than they would at a barrier wall member 140 constituted with a single plate having through holes formed therein. Accordingly, if all the plate members constituting the barrier wall member 140 are formed by using a metal such as aluminum, a greater number of metal atoms will be ejected from the surfaces of the individual surfaces of the plurality of plate members as the surfaces are sputtered by the hydrogen ions 152, than at a barrier wall member constituted with a single plate member. Thus, the multiple-plate barrier wall member will more readily give rise to problems such as scattering of particles onto the wafer W and metal contamination.

In the embodiment, the plurality of plate members constituting the barrier wall member 140, i.e., the upper plate member 142 and the lower plate member 144 in FIG. 1, are all constituted of an insulating material such as quartz, which sets the upper plate member 142 and the lower plate member 144 in an electrically floating state and thus inhibits the generation of an electrical potential between the barrier wall member 140 and the hydrogen plasma.

As described above, the generation of electrical potential between the barrier while 140 and the hydrogen plasma is inhibited by adopting the embodiment. In other words, the velocity of the hydrogen ions 152 can be kept down as they are captured at the upper plate member 142 and the lower plate member 144 and thus, particles of the insulating material constituting the plate members are not ejected from the surfaces of the plate members even when the hydrogen ions 152 collide with the plate member surfaces. As a result, the surfaces inside the processing chamber 102 and the surface of the wafer W on the stage 106 are kept in a clean state, thereby assuring desirable processing results for the wafer W.

Even though the upper plate member 142 and the lower plate member 144 are in an electrically floating state, a sheath is formed at their surfaces and an electrical potential high enough to capture hydrogen ions is generated via the sheath between the barrier wall member 140 and the hydrogen plasma. Thus, the hydrogen ions 152 can be captured with a high level of reliability at the barrier wall member 140.

In addition, even if the surfaces of the upper plate member 142 and the lower plate number 144 constituted of the insulating material are sputtered by the hydrogen ions 152, particles of the insulating material will simply settle onto the plate member surfaces in the vicinity and are not ejected from the plate member surfaces. Such particles having settled on the plate member surfaces can be removed with ease simply by wiping the surfaces with a chemical such as hydrogen fluoride.

At the barrier wall member 140 in the embodiment, the hydrogen ions 152 and the ultraviolet light 154 are blocked since the through holes 142a and 144a at the plate members 142 and 144 are formed with an offset relative to each other. In other words, unlike at a barrier wall member 140 in the related art constituted with a single plate member, the through holes 142a and 144a do not need to assume a smaller diameter in order to disallow passage of the hydrogen ions 152. Since the through holes 142a and 144a do not need to assume a very small hole diameter, smooth passage of the hydrogen radicals 150 is assured. Namely, at the barrier wall member 140 in the embodiment, the hole diameter of the through holes 142a and 144a at the plate members 142 and 144 can be set freely in correspondence to the specific type of processing that the wafer W is to undergo and thus, the hydrogen radicals 150 can be delivered over to the wafer W in a sufficient quantity as required in the specific type of processing the wafer W is undergoing.

### (Results of Tests Conducted by Using the Plasma Processing Apparatus)

Next, the results of tests conducted by using the plasma processing apparatus 100 achieved in the embodiment are explained. In the tests, wafers W with an oxide film used as, for instance, transistor gates, a low-k film and a photoresist film formed thereupon in this order, each underwent an ashing process in order to remove the photoresist film and the quantity of hydrogen ions reaching the surface of the wafer W, the quantity of ultraviolet light reaching the wafer surface, the transistor (gate oxide film) quality acceptability rate and the extent of damage to the low-k film were individually measured.

It is to be noted that the transistor quality acceptability rate was determined by judging whether or not the gate oxide film sustained the insulated state. In addition, the extent of damage to the low-k film was determined based upon the quantity of the low-k film having undergone the ashing process, which was dissolved in the hydrogen fluoride solution (the depth of erosion).

In the tests, the ashing process was executed under the following processing conditions. The pressure inside the processing chamber 102 was adjusted to 1.25 Torr, and an induction field was formed inside the plasma generation chamber 104 by supplying high-frequency power of, for instance, 3 kW from the high-frequency power source 118 to the coil 116 while delivering a mixed gas containing hydrogen gas and helium gas (with the mixing ratio of the hydrogen gas set to 4%) into the plasma generation chamber 104 at a flow rate of 9000 sccm. In addition, the power supplied from the heater power source 114 to the heater 112 was set so as to heat the wafer W to 300° C.

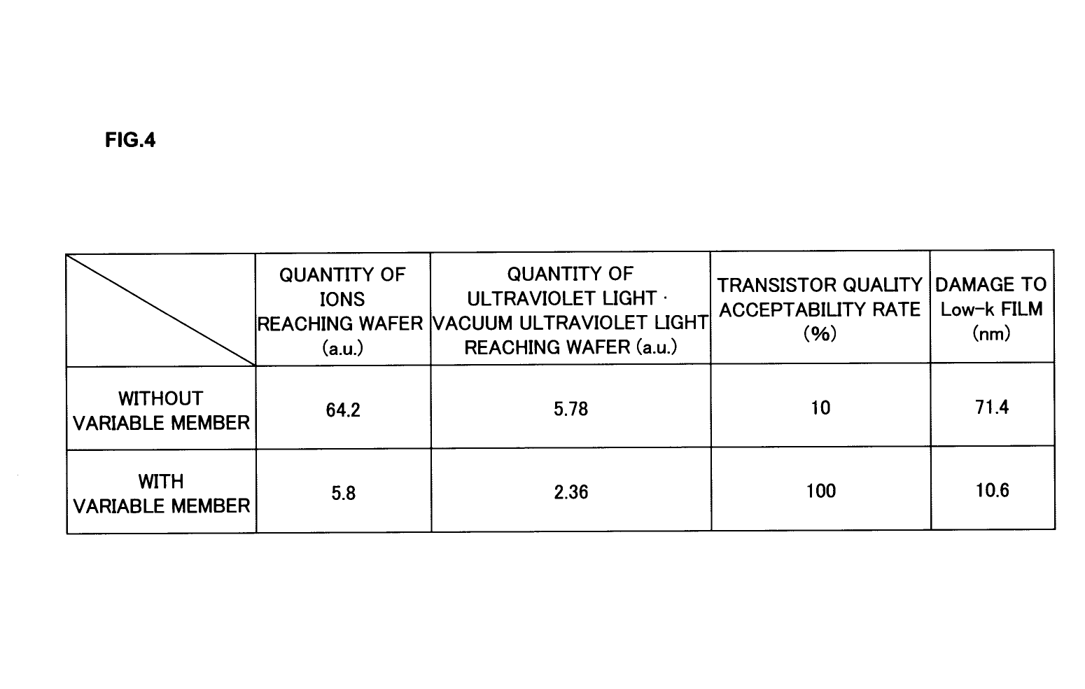

In order to confirm the effect of the barrier wall member 140 achieved in the embodiment, tests were conducted with (barrier wall member present) and without (barrier wall member absent) the barrier wall member 140 in the plasma processing apparatus 100. FIG. 4 presents the measurement results. The test results presented in FIG. 4 indicate that the quantity of hydrogen ions reaching the wafer W was reduced to approximately 1/11 and the quantity of ultraviolet light reaching the wafer W, too, was reduced to less than ½ when the wafer W was processed in the plasma processing apparatus with the barrier wall member installed therein, compared to the corresponding measurement results obtained by measuring the wafer W processed in the plasma processing apparatus 100 without the barrier wall member. In other words, the barrier wall member 140 blocks most of the hydrogen ions and the ultraviolet light traveling from the plasma generation chamber 104 toward the processing chamber 102.

The significant reductions in the quantities of hydrogen ions and ultraviolet light reaching the wafer W are reflected in the transistor quality acceptability rate and the damage to the low-k film, which are markedly different from the corresponding measurement results obtained from the wafer W processed in the plasma processing apparatus without the barrier wall member. More specifically, while the transistor quality acceptability rate measured at the wafer W processed in the plasma processing apparatus without the barrier wall member was 10%, a great improvement was achieved by installing the barrier wall member in the plasma processing apparatus to a transistor quality acceptability rate of 100%. In addition, the damage to the low-k film at the wafer W processed in the plasma processing apparatus 100 with the barrier wall member installed therein was greatly reduced with the quantity of the low-k film dissolved in the hydrogen fluoride solution (the depth of erosion) reduced to approximately 1/7 of the corresponding measurement results at the wafer W processed in the plasma processing apparatus without the barrier wall member, demonstrating a considerable improvement in the film quality. It is to be noted that a lowered extent of metal contamination at the wafer W, too, is assumed to contribute to the improvement in the transistor quality acceptability rate.

In the embodiment described above, which includes the barrier wall member 140, the hydrogen radicals 150 alone among the hydrogen radicals 150, the hydrogen ions 152 and the ultraviolet light 154 traveling from the plasma generation chamber 104 toward the processing chamber 102, are supplied over to the wafer W. As a result, the desired processing such as ashing the photoresist film on the wafer W can be executed by using the hydrogen radicals alone while minimizing the damage to a film present on the wafer W attributable to the hydrogen ions 152 and the ultraviolet light 154. Consequently, desirable processing results are obtained.

Metal atoms are certain to scatter into the processing chamber if even one of the plurality of plate members constituting the barrier wall member is a metal plate. However, the barrier wall member 140 in the embodiment is constituted with a plurality of plate members all formed by using an insulating material and thus, no metal atoms are scattered into the processing chamber. Also, the extent to which the surfaces at the barrier wall member 140 become sputtered as the hydrogen ions 150 are captured at the barrier wall member 140 is effectively reduced. Thus, particles of the insulating material constituting the plate members at the barrier wall member 140 do not scatter into the processing chamber 102, either. Consequently, the quality of the film at the wafer W having undergone the hydrogen radical processing can be maintained at a desirable level.

It is to be noted that while an explanation is given in reference to the embodiment on an example in which the through holes 142a and 144a are respectively formed evenly over the entire surfaces of the plate members 142 and 144 constituting the barrier wall member 140, the present invention is not limited to this example. For instance, by adjusting the pattern with which the through holes 142a or 144a are formed within the in-plane area of the plate member 142 or 144, the quantity of hydrogen radicals to pass through the barrier wall member 140 can be controlled within the in-plane area. Through these measures, the in-plane uniformity of the wafer processing can be adjusted. More specifically, the wafer processing rate may be lowered over a specific area by forming no through holes 142a or 144a over the corresponding area at least at either of the plate members 142 and 144, whereas the wafer processing rate may be increased over a specific area by forming the through holes 142a and 144a at both plate members.

Since the in-plane uniformity of the wafer processing may be affected by the processing conditions or the plasma density distribution within the in-plane area, the in-plane uniformity of the wafer processing can be further improved by determining the positional arrangement of the through holes 142a and 144a based upon the results (e.g., ashing rate) of in-plane uniformity processing tests executed on wafers W in the plasma processing apparatus 100.

### (In-Plane Uniformity Test Results)

In reference to drawings, the results of tests conducted to check wafer processing in-plane uniformity by altering the positional arrangement of the through holes 144a within the in-plane area of the lower plate number 144 in the barrier wall member 140 are explained. In the tests, test wafers W with a diameter of 300 mm, each having a photoresist film formed over the entire surface thereof, underwent an ashing process in order to remove the photoresist film and the ashing rate distribution within the wafer surface plane was measured.

In the tests, the ashing process was executed under the following processing conditions. The pressure inside the processing chamber 102 was adjusted to 1.5 Torr, and an induction field was formed inside the plasma generation chamber 104 by supplying high-frequency power of, for instance, 5 kW from the high-frequency power source 118 to the coil 116 while delivering a mixed gas containing hydrogen gas and helium gas into the plasma generation chamber 104 at a flow rate of 2500 sccm. In addition, the power supplied from the heater power source 114 to the heater 112 was set so as to heat the wafer W to 300° C. The ashing process was executed over a period of five minutes.

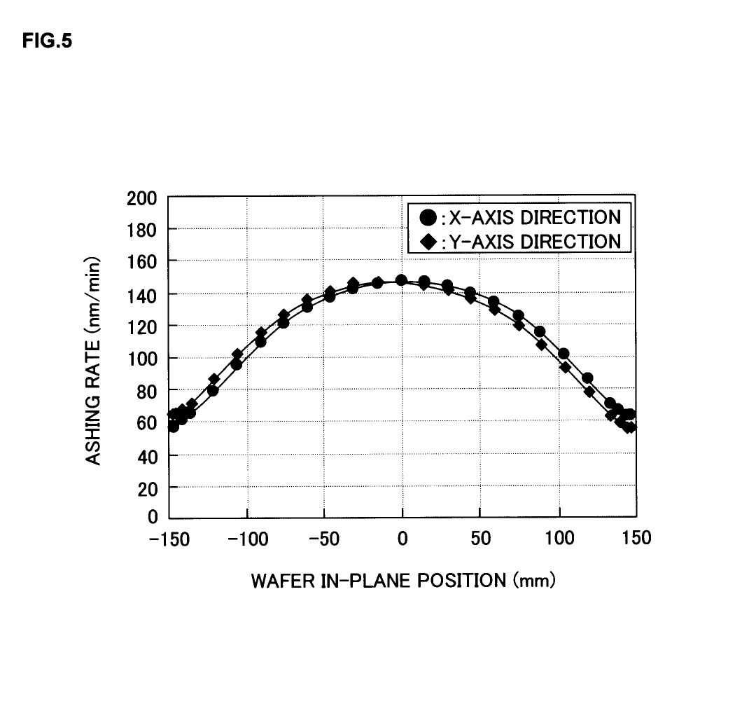

FIG. 5 presents, for purposes of comparative reference, the ashing rate distribution measured within the wafer surface plane of a wafer having undergone the ashing process with the barrier wall member 140 disengaged from the plasma processing apparatus 100. The graph in FIG. 5 was prepared by setting an x, y coordinate system within the plane of the wafer W with the center of the wafer W set as the origin point, measuring the extent of ashing achieved at a plurality of points on the x-axis and the y-axis and then calculating the ashing rate achieved at each point.

As is clear from the graph in FIG. 5, the average ashing rate measured at the wafer W processed in the plasma processing apparatus without the barrier wall member 140 is considerable, at 103.2 nm/min, the in-plane uniformity, at ±44.0% indicates an extremely large variance. More specifically, the ashing rate at the center of the wafer W is much greater than that at the edge of the wafer W. This tendency is assumed to be attributable to a greater quantity of hydrogen radicals supplied toward the center of the wafer W compared to the quantity of hydrogen radicals supplied to the edge of the wafer W.

Accordingly, the ashing rate in-plane uniformity may be improved by reducing the quantity of hydrogen radicals supplied to an area around the center of the wafer W relative to the quantity of hydrogen radicals supplied to the areas around the edge of the wafer. In order to prove the accuracy of this idea, a test similar to that described above was conducted by using a barrier wall member 140 with its lower plate member 144 having no through holes 144a formed over the center (a through hole absent area) of the in-plane area facing opposite the central area of the wafer W.

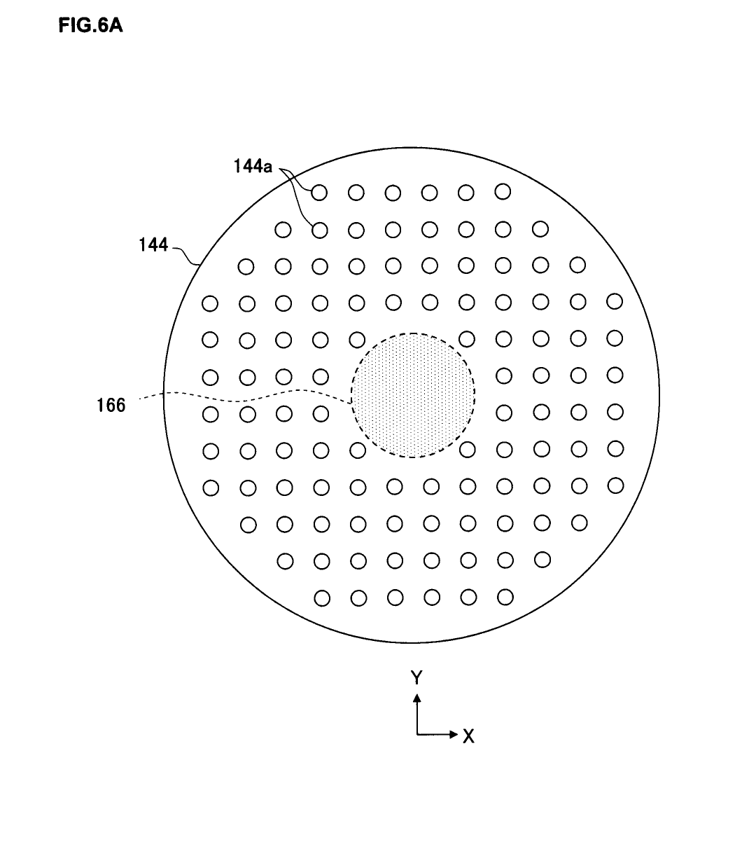

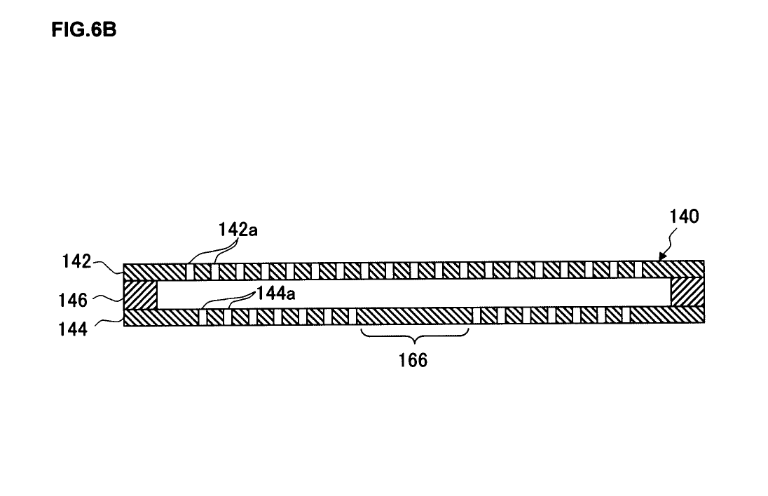

FIG. 6A presents an example of a positional arrangement that may be assumed for the through holes 144a at the lower plate member 144 of such a barrier wall member 140. FIG. 6B is a sectional view of a barrier wall member 140 constituted with the lower plate member 144 in FIG. 6A and an upper plate member 142 with through holes 142a formed over the entire surface thereof. At the barrier wall member 140 shown in FIGS. 6A and 6B, a central area 166 is designated as a through hole absent area and through holes 144a are evenly formed over the peripheral area further outside relative to the central area 166.

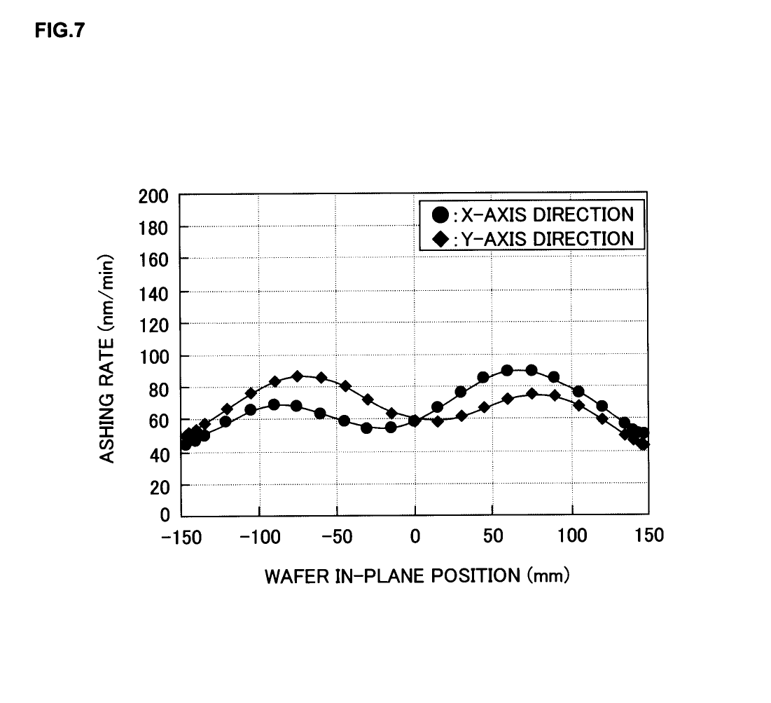

FIG. 7 presents the results obtained by detecting the ashing rate distribution within the surface plane of a wafer having undergone an ashing process similar to that described earlier in the plasma processing apparatus with the barrier wall member 140 shown in FIG. 6B installed therein. As shown in FIG. 7, while the overall ashing rate average is lowered to 66.2 nm/min, the in-plane uniformity was improved to ±35.8% at the wafer having undergone the ashing process in the plasma processing apparatus having installed therein the barrier wall member 140 with the central area 166 designated as a through hole absent area. FIG. 7 also indicates that compared to the ashing rate over the central area graphed in FIG. 5, the ashing rate was lower near the center of the wafer W, achieving better consistency. In short, by using a barrier wall member 140 such as that shown in FIG. 6B, the quantity of hydrogen radicals to be supplied to the wafer W can be regulated so that they are supplied in a smaller quantity to an area near the center of the wafer W compared to the quantity of hydrogen radicals supplied to areas near the edge of the wafer W.

However, the ashing rate graph presented in FIG. 7 indicates that the ashing rate over the area between the center of the wafer W and the edge of the wafer W was higher than the etching rates calculated for the center and the edge of the wafer W. This means that the quantity of hydrogen radicals to be supplied to the area between the center and the edge may also be regulated, in addition to the quantity of hydrogen radicals to be supplied to the area near the center of the wafer W, so as to further improve the in-plane uniformity. Accordingly, a test similar to those described earlier was conducted by using a barrier wall member 140 with a lower plate member 144 having no through holes 144a formed (through hole absent area) over a ring-shaped area (the area facing opposite an area of the wafer W between the wafer center and the wafer edge), which surrounds the central area of the lower plate member over a distance, as well as over the central area.

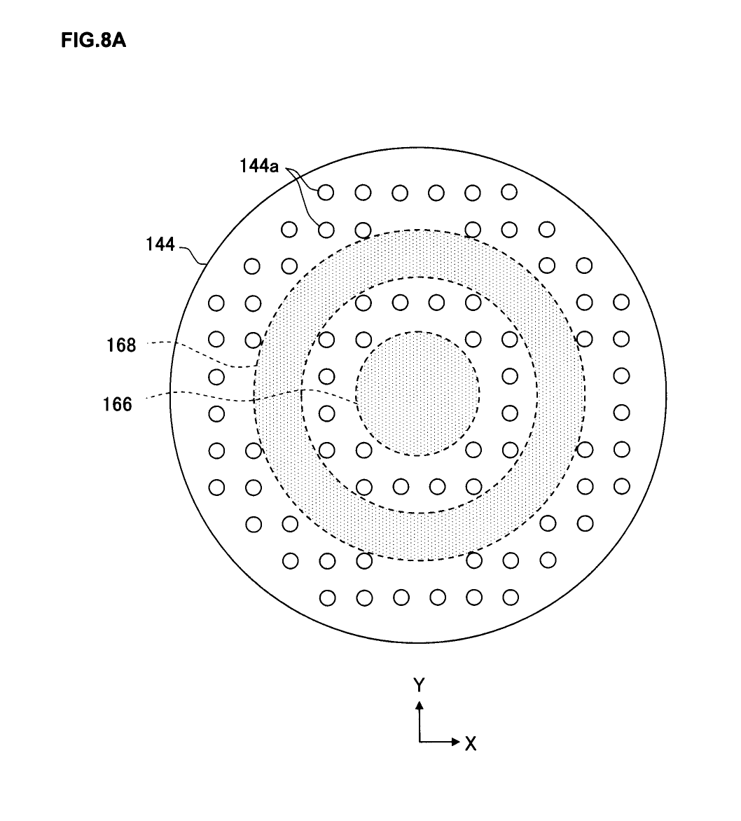

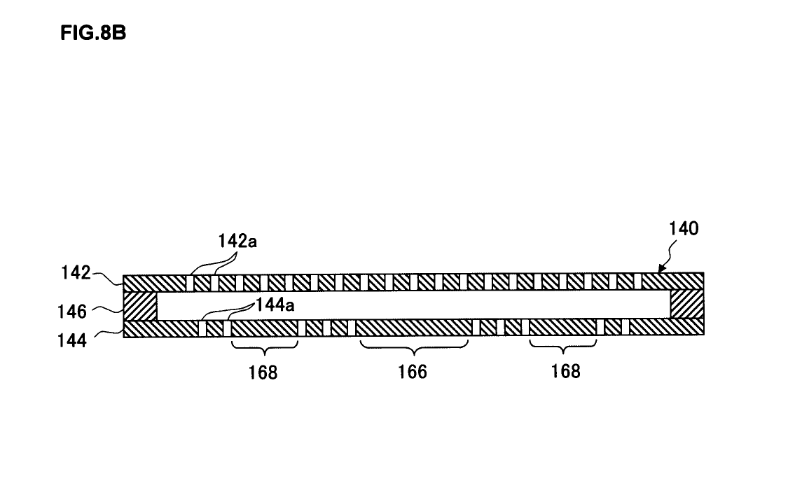

FIG. 8A presents an example of a positional arrangement that may be assumed for the through holes 144a at the lower plate member 144 of such a barrier wall member 140. FIG. 8B is a sectional view of a barrier wall member 140 constituted with the lower plate member 144 in FIG. 8A and an upper plate member 142 with through holes 142a formed over the entire surface thereof. At the barrier wall member 140 shown in FIGS. 8A and 8B, a central area 166 and a ring-shaped area 168 are designated as through hole absent areas and through holes 144a are evenly formed over the area ranging between the central area 166 and the ring-shaped area 168 and the edge area further outward relative to the ring-shaped area 168.

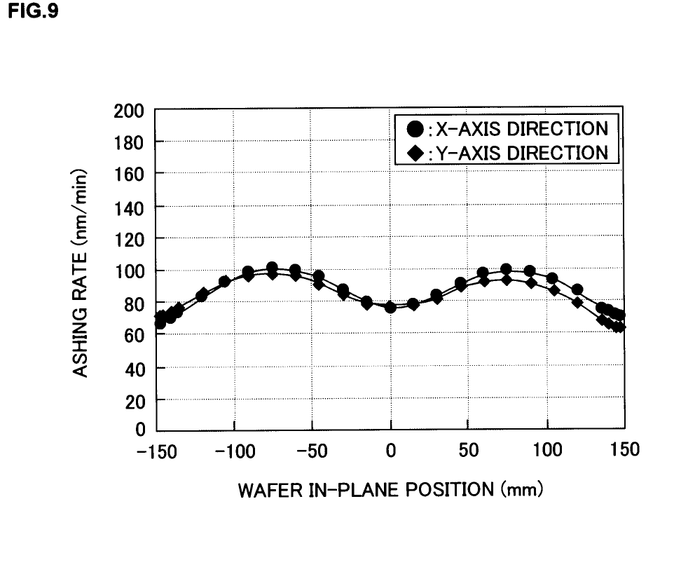

FIG. 9 presents the results obtained by detecting the ashing rate distribution within the surface plane of a wafer having undergone an ashing process similar to that described earlier in the plasma processing apparatus with the barrier wall member 140 shown in FIG. 8B installed therein. As FIG. 9 indicates, a higher ashing rate average of 82.6 nm/min was achieved at the wafer having undergone the ashing process in the plasma processing apparatus having installed therein the barrier wall member 140 with the central area 166 and the ring-shaped area 168 designated as through hole absent areas, compared to that indicated in FIG. 7. In addition, an in-plane uniformity value of ±23.0% indicates even better consistency than that indicated in FIG. 7, which is a very significant improvement over that shown in FIG. 5. In short, by using a barrier wall member 140 such as that shown in FIG. 8B, the quantity of hydrogen radicals to be supplied to the area between the center and the edge of the wafer W, as well as the quantity of hydrogen radicals to be supplied to an area around the center of the wafer W, can be adjusted.

By adjusting the positional arrangement of the through holes 142a and 144a within the in-plane areas of the plate members 142 and 144 constituting the barrier wall member 140 as described above, the quantity of hydrogen radicals to pass through the barrier wall member 140 can be regulated via the in-plane areas. This, in turn, makes it possible to assure better uniformity with respect to the quantity of hydrogen radicals supplied to the whole surface area of the wafer W, so as to improve the in-plane uniformity of the processing executed on the wafer W, which may be represented by, for instance, the ashing rate. Consequently, better processing results can be achieved in wafer processing.

It is to be noted that while an explanation is given above on examples in which only the lower plate member 144 of the barrier wall member 140 includes an area (areas) where no through holes 144a are formed, the present invention is not limited to these examples. For instance, the upper plate member 142 at the barrier wall member 140 alone may include an area with no through holes 142a formed therein, or both the upper plate member 142 and the lower plate member 144 may include areas with no through holes 144a formed therein.

In addition, while an explanation is given above in reference to examples in which at least one of the plurality of plate members constituting the barrier wall member includes an area with no through holes formed therein so as to regulate the quantity of hydrogen radicals supplied to the wafer W within the in-plane area of the wafer W, the present invention is not limited to these examples and instead, different in-plane areas at a plate member may include through holes formed at varying levels of density. In more specific terms, at least at one plate member among the plurality of plate members constituting the barrier wall member, a plurality of through holes may be formed with the lowest level of density at the center with the density gradually increasing toward the edge of the plate member within the in-plane area of the plate member. Through these measures, too, the quantity of hydrogen radicals to be supplied to an area around the center of the wafer W is reduced compared to the quantity of hydrogen radicals to be supplied to areas near the edge of the wafer W, so as to improve the wafer processing in-plane uniformity.

Alternatively, different in-plane areas at the plate member may include through holes assuming different diameters. More specifically, at least at one plate member among the plurality of plate members constituting the barrier wall member, a plurality of through holes may be formed so that the through holes diameter, smallest at the center, gradually increases toward the edge within the in-plane area of the plate member. Through these measures, too, the quantity of hydrogen radicals to be supplied to an area around the center of the wafer W is reduced compared to the quantity of hydrogen radicals to be supplied to areas near the edge of the wafer W, so as to improve the wafer processing in-plane uniformity.

While the invention has been particularly shown and described with respect to preferred embodiment thereof by referring to the attached drawings, the present invention is not limited to this example and it will be understood by those skilled in the art that various changes in form and detail may be made therein without departing from the spirit, scope and teaching of the invention.

For instance, the present invention may be adopted in any of various types of plasma processing apparatuses that execute different types of plasma processing on processing target substrates, such as etching and film formation, as well as ashing. In addition, the present invention may be adopted in a remote plasma-type plasma generation chamber in which plasma is generated in a space distanced from the wafer W, instead of the downflow-type plasma generation chamber described above.

What is claimed is:

1. A plasma processing apparatus that executes a specific type of processing on a processing target substrate with hydrogen radicals generated by exciting a hydrogen-containing processing gas to a plasma state, comprising:
a plasma generation chamber where plasma is generated by exciting said processing gas;
a processing chamber communicating with said plasma generation chamber;
a stage disposed inside said processing chamber, upon which the processing target substrate is placed; and
a barrier wall member separating said plasma generation chamber from said processing chamber, wherein:
said barrier wall member includes a plurality of plate members stacked one on top of another with a gap therebetween;
a plurality of through holes through which the hydrogen radicals travel are formed at each of said plate members;
said through holes and a given plate member are formed with an offset relative to said through holes at another plate member so that said through holes at different plate members are not aligned with each other; and
said plate members are all constituted of an insulating material through which ultraviolet light cannot be transmitted.

2. A plasma processing apparatus according to claim 1, wherein:
said insulating material contains silicon oxide.

3. A plasma processing apparatus according to claim 1, wherein:
said insulating material contains aluminum oxide.

4. A plasma processing apparatus according to claim 1, wherein:
an in-plane area of at least one of said plurality of plate members includes a central area with no through holes formed therein and an outer area located further outward relative to said central area, where said plurality of through holes are formed.

5. A plasma processing apparatus according to claim 1, wherein:
an in-plane area of at least one of said plurality of plate members includes a central area and a ring-shaped area surrounding said central area with no through holes formed therein, and an area located between said central area and said ring-shaped area and an outer area located further outward relative to said ring-shaped area, where said through holes are formed.

6. A plasma processing apparatus according to claim 1, wherein:
at least at one of said plurality of plate members said plurality of through holes are formed so that the density of through holes, which are formed relatively sparsely at a central area, increases toward the edge of said plate member.

7. A plasma processing apparatus according to claim 1, wherein:
said plurality of through holes formed in an in-plane area of at least one of said plurality of plate members assume a smallest hole diameter at a central area and the diameter of said through holes gradually increases toward the edge of said plate member.
